(19) United States
(12) Patent Application Publication
(10) Pub. No.: US 2006/0150053 A1
(43) Pub. Date: Jul. 6, 2006

(54) Switching method for mdc/scalable coding

(75) Inventors: Mihaela van der Schaar, Sacramento, CA (US); Qiong Li, Tappan, NY (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 10/538,447

(22) PCT Filed: Dec. 11, 2003
(86) PCT No.: PCT/IB03/05874

§ 371 Date: Dec. 1, 2005

Related U.S. Application Data
(60) Provisional application No. 60/433,313, filed on Dec. 13, 2002.

(51) Int. Cl. H03M 13/00

(52) U.S. Cl. 714/752

(57) ABSTRACT

A system and method is provided for switching between multiple description coding and scalable coding that is dependent on the network characteristics and uses forward error correction (FEC) and scalable or prioritized video.

### BACKGROUND OF THE INVENTION

1. Field of the Invention

The present invention relates to a system and a method for on-the-fly switching between multiple description coding (MDC) and scalable coding (SC), based on channel characteristics. The system and method of the present invention can also be realized using a scalable or prioritized coded stream and forward error correction (FEC) protection.

2. Description of Related Art

Multiple Description Coding (MDC) is aimed at transmission over best-effort networks, while scalable coding (SC) is often aimed at transmission over networks with some quality-of-service (QoS) guarantee. Multiple description coding (MDC) is a form of MD coding designed to combat the problem of error propagation by coding the video into multiple independently decodable streams, each with its own prediction process and state. If one stream is lost, the other streams can still be decoded to produce usable video, and, most importantly, the correctly received streams provide bi-directional (previous and future) information that enables improved state recovery of the corrupted stream. A path diversity transmission system for packet networks can be employed for MDC transmission that explicitly sends different subsets of packets over different paths, as opposed to the default scenarios where the packets proceed along a single path, thereby enabling the end-to-end video application to effectively see a virtual channel with improved loss characteristics. For example, the application effectively sees an average path behavior, which generally provides better performance than seeing the behavior of any individual random path.

Layered or scalable approaches essentially prioritize data and thereby support intelligent discarding of the data (the enhancement data can be lost or discarded while still maintaining usable video), however the video can be completely lost if there is an error in the base layer.

Multiple Description Coding attempts to overcome this problem by coding a signal into multiple bitstreams such that any one bitstream can be used to decode a baseline signal, and any additional bitstreams improve upon the quality of the reconstructed signal.

MDC can also be successfully combined with scalable coding, to improve the coding efficiency of scalable coding when path diversity can be used. For instance, if the network can prioritize packets, scalable coding can be used for coding the various descriptions.

A generalized Multiple Description (MD) source coding technique that employs Forward Error Correction (FEC) Codes is one approach that has been proposed to achieve robust and efficient video streaming and multicast over best effort networks (e.g. the Internet), see R. Puri and K. Ramchandran, “Multiple Description Source Coding Through Forward Error Correction Codes,” 33^{rd} Asilomar Conference on Signals, Systems and Computers, Pacific Grove, Calif. , October 1999, which is hereby incorporated by reference as if fully set forth herein. In this approach, a Progressive bitstream from the source coder is partitioned into N layers or quality levels and can be scalably coded or not. These streams can be prioritized as shown in FIG. 1. Then, FEC is used to create N partitions (see FIG. 2). These N partitions are then transmitted using different channels (e.g., using different physical paths or different routes).

Alternatively, a progressive bitstream can be also used for prioritized transmission using different channels and FEC can also be used to provide additional resilience to the encoding, see P. A. Chou, A. E. Hohr, A. Wang and S. Mehrotra, “FEC and Pseudo-ARQ for Receiver Driven Hierarchical FEC,” DCC, Snowbird, Utah, March 2000, which is hereby incorporated by reference as if fully set forth herein.

### SUMMARY OF THE INVENTION

MDC coding is targeted to best effort transmission, while SC focuses on transmission over networks with QoS that support prioritized transmission and/or differential protection. Hence, if the channel characteristics change dynamically or across the network as the stream traverses different networks, one or the other method can become inefficient and is no longer robust. The system and method of the present invention allows for flexible adaptation to these varying channel characteristics, while also providing the advantage that the video and channel data can be coded just once and the video stream can still be adapted to varying network characteristics.

The present invention comprises a pair of multi-channel transmission protocols (see FIGS. 4 and 5) and a mapping (see FIG. 6) between and the descriptions of an MDC coded stream (see FIG. 2) and the layers of an SC coded stream (see FIG. 3) that use FEC as applied to an initial scalable or prioritized video stream. The appropriate multi-channel transmission protocol is used to transmit the coded stream, which, when received at a gateway, is mapped between MDC and SC as network condition dictate, see FIG. 7.

In a preferred embodiment a raw video stream is coded so that the coded information is prioritized 703. This prioritized video stream 703 is then respectively rearranged and transmitted either as an MDC or SC stream, depending on channel conditions, using the respective format of FIG. 2 and FIG. 3 and the respective multi-channel streaming model of FIG. 5 and FIG. 4. When the packet of this stream arrive at a gateway, the choice of MDC or SC is reevaluated in light of the then current network conditions 707. If conditions indicate the transmission protocol is no longer efficient, then a mapping between the MDC and SC encoded stream is effected to rearrange the data and the appropriate multi-channel streaming system is used to transmit the rearranged video data. The underlying coding of the prioritized video stream is not changed.

This invention can be used in the implementation of multimedia gateways which require robust streaming video and multimedia servers that play media from networked storage.

### BRIEF DESCRIPTION OF THE DRAWINGS

FIG. 1 illustrates a progressive bitstream from the source coder that has been partitioned into N layers or quality levels.

FIG. 2 illustrates N-description generalized MD codes using forward error correction (FEC) codes.

FIG. 3 illustrates transmission of a scalable coding (SC) stream using different unequal error protection provided by FEC.

FIG. 4 illustrates a multi-channel streaming system for a scalable-video and protection transmission.

FIG. 5 illustrates a multi-channel streaming system for a multiple-description and protection transmission.

FIG. 6 illustrates a mapping between MDC and SC packet streams, according to the present invention.

FIG. 7 illustrates an end-to-end transmission and processing events associated with transmission of a raw video stream between a sender and a receiver, according to the present invention.

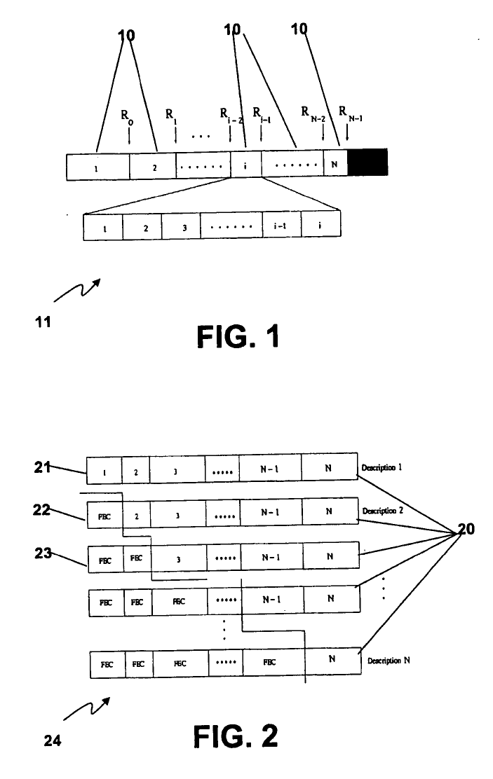

### DETAILED DESCRIPTION OF PREFERRED EMBODIMENTS

Currently, network switches (gateways) in the internet do not interpret either the structure or content of packets, treating all packets alike. Further, gateways do not provide congestion feedback. Only end-to-end feedback (i.e., from the receiver) is available to a sender, and the sender typically has to probe the network to obtain information regarding connection conditions. Once encoded, and encoded video stream cannot be reformatted in transit to accommodate changing network conditions.

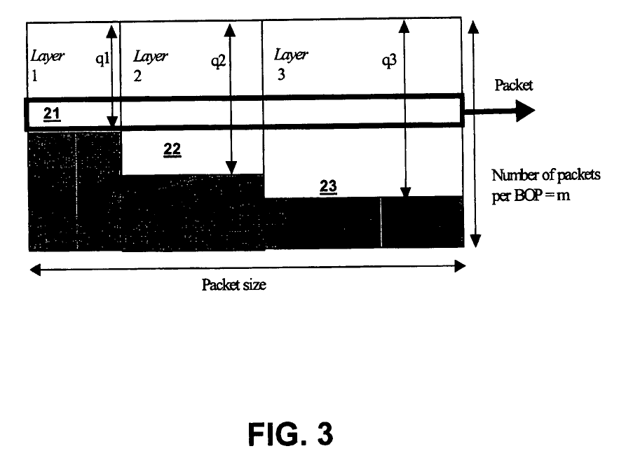

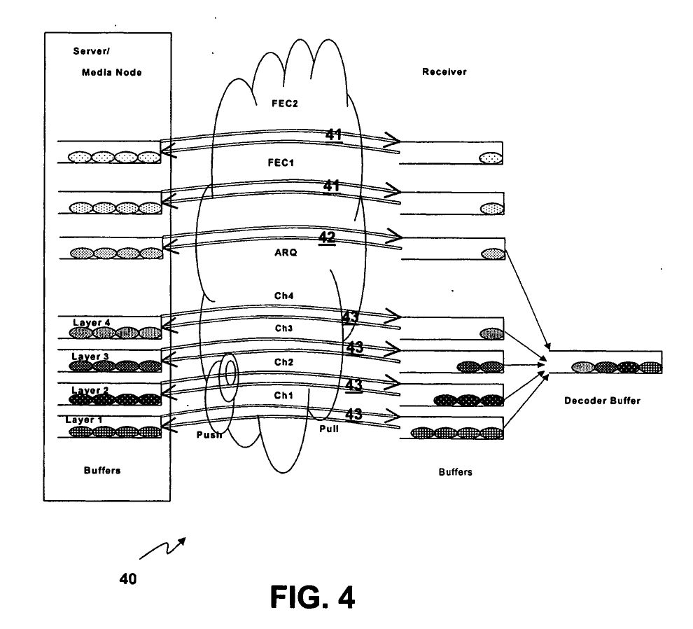

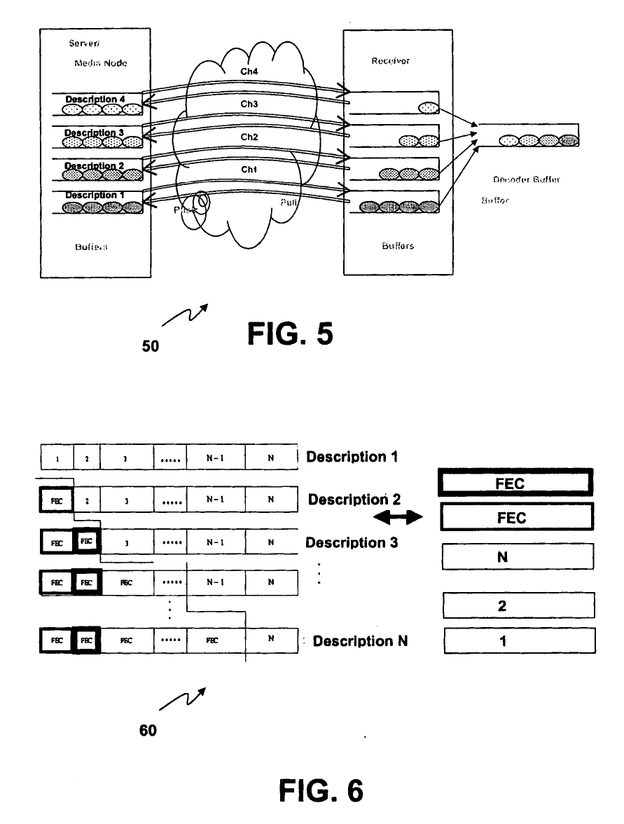

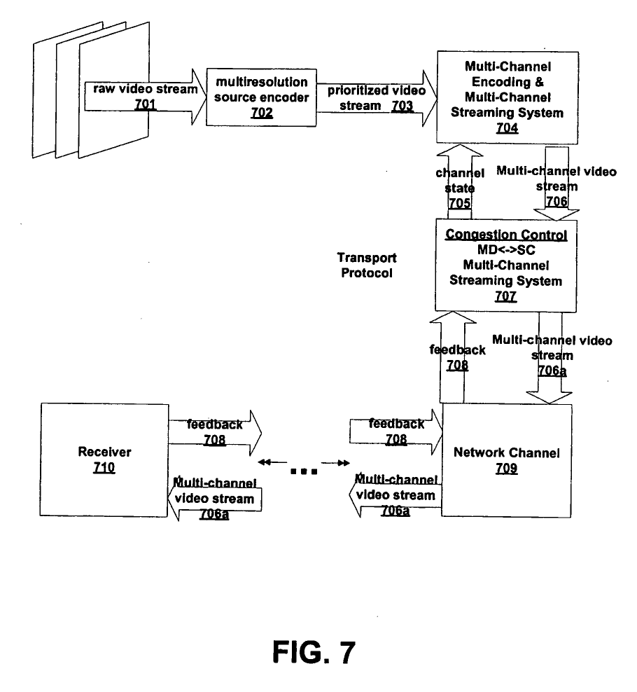

This mismatch between the needs of streaming video and the Internet transport protocol is addressed by the system and method of the present invention. According to the present invention, a prioritized coded video stream is formatted using the best choice of MDC (FIG. 2) and SC (FIG. 3) and then transmitted according to a corresponding multi-channel streaming protocol system (FIGS. 5 and 4, respectively), wherein both the format and the streaming protocol are according to the system and method of the present invention. Then, at each gateway in the path from sender to receiver, the choice of MDC and SC is reevaluated in view of existing channel conditions and if a change to the other format is indicated, a mapping of the underlying prioritized coded stream between MDC and SC is accomplish, see FIG. 6. The mapping is accomplished on-the-fly, for a whole frame, e.g., for a block of packets, and thus sufficient buffer space is required at each gateway for the mapped stream and transmission of the mapped stream 401, 402. There is no need for any recoding/transcoding of the video data or channel coding at any gateway.

FEC based MD coding transforms a “prioritized” multi-resolution bit stream into an “unprioritized” MD packet stream. Given a progressive bit stream marked at n different positions 10, see FIG. 2, each corresponds to a quality or resolution layer. The i^{th} layer should be decodable when i descriptions get through. This requires splitting the i^{th} quality layer into i equal parts 11 and applying Reed Solomon encoding to obtain the contribution from the i^{th} level to each of the n-descriptions the contribution from each of the n quality levels are concatenated to form the n descriptions, as illustrated in FIG. 2. In this way, the MD-FEC encoder of a preferred embodiment transforms the input progressive SC encoded bitstream to a robust packet MD stream.

The system and method of the present invention allows transmission of both unicast & multicast applications.

Thus, a preferred embodiment of the present invention addresses the following two scenarios:

A. Best-effort→Gateway→QoS Network

Originally the data is coded using any coding method that prioritizes the stream such that the prioritized components of the stream can be mapped across n-description and FEC coded. By way of example and not limitation, a progressive stream is SC encoded and the packets of the base layer BL and various enhancement layers EL are split across multiple descriptions and FEC coded, as illustrated in FIG. 2. Then these multiple descriptions are transmitted as a multi-channel MDC stream, as illustrated in FIG. 5.

In splitting the SC video stream across the multiple descriptions the Nsource layers of decreasing importance are protected by N channel codes of decreasing strength. FEC is used because of its relatively small transmission delay. FEC adds redundant information to a compressed video bit stream to enable reconstruction of the original video in case of packet loss.

Then, if a change in network conditions indicates a change in MDC to SC when the stream reaches a gateway, the various streams are collected into the format illustrated in FIG. 3 and retransmitted as separate layers, separate FEC streams and even may include an ARQ stream by using the multi-channel SC streaming model shown in FIG. 4. That is, the FEC packets in FIG. 2 are transmitted in separate tracks. Some of the FEC packets can be discarded if the channel conditions are good. Also, a separate Automatic Repeat reQuest (ARQ) track, can be transmitted by copying some of the most important video packets and transmitting them in a delayed fashion.

B. QoS Network→Gateway→Best-Effort

The raw video stream is progressively encoded and the prioritized layers are FEC coded and organized as illustrated in FIG. 3 and then the layers, FEC codes and even an ARQ stream are transmitted as a multi-channel SC stream, as illustrated in FIG. 4. Then, at a gateway if channel conditions indicate a change is needed, the SC streams are reorganized using the mapping of the present invention (see FIG. 6) and transmitted using a multi-streaming system dedicated to MDC, as illustrated in FIG. 5.

C. Mapping Between MDC and SC

In either scenario, changing between MDC and SC can be done on the fly and does not require any recoding/transcoding of the video data or channel coding (see FIG. 6).

D. Multi-Channel Streaming Model

In another preferred embodiment, the multi-channel streaming system is designed to allow for multi-channel transmission of either MDC or SC by enabling multiple hinting tracks associated with the two video-coding and channel coding formats.

E. Encoding the Raw Video Stream

This embodiment can be realized with any coder that can prioritize the coded information. For instance, a scalable coder (e.g. FGS, wavelet coding) or non-scalable coder (e.g. a coder that prioritizes I, P and B-frames or prioritizes the data in several partitions using different priorities, using for instance data partitioning etc.) can be used.

Since other modifications and changes appropriate to particular network requirements and environments will be apparent to those skilled in the art, this invention is not considered limited to the examples chosen for purposes of this disclosure, and covers all changes and modifications which are within the scope of the appended claims.

We claim:

1. An apparatus for a gateway to switch between a multi-channel streaming system for multiple-description and protection transmission and a multi-channel streaming system for scalable-video and protection transmission based on network channel conditions, comprising:
a multi-channel streaming system for transmitting and receiving at least two coding formats
a. scalable-video and protection format of a prioritized encoded packet stream that has been further encoded by an FEC-MDC encoder;
b. multiple description and protection format of a prioritized encoded packet stream that has been further encoded by an FEC-MDC encoder; and
a mapping mechanism for mapping between the scalable-video and multiple-description format of a received multi-channel video stream such that video data coding and channel coding of the FEC-MDC encoded prioritized encoded packet stream is preserved,
wherein, when a multi-channel packet stream is received by a gateway and network channel conditions indicate a change needs to be made in the format of the packet stream, the received stream is mapped by the mapping mechanism between the multiple-description format and the scalable-video format and then transmitted by the gateway using the multi-channel streaming system.

2. The apparatus of claim 1, wherein the multi-channel streaming system further comprises a plurality of hinting tracks, each of said plurality of hinting tracks being associated with at least one of said at least two coding formats.

3. The apparatus of claim 1, wherein said multi-channel streaming system further comprises:
a first multi-channel streaming system for transmitting and receiving a video stream according to said scalable-video and protection format; and
a second multi-channel streaming system for transmitting and receiving a video stream according to said multiple-description and protection format.

4. The apparatus of claim 3, wherein said first multi-channel streaming system further comprises:
a plurality of channels for transmission of a prioritized layer as a separate stream;
at least once FEC channel for transmission of at least one separate stream comprising FEC codes, wherein an FEC packet may be discarded based on good network channel conditions; and
an Automatic Repeat reQuest channel for transmission of at least a most important video packet of said received video stream, wherein said ARQ channel is transmitted in a delayed fashion.

5. An apparatus for a source to encode a raw video stream for transmission and transmit the encoded stream over a multi-channel streaming system based on network channel conditions, comprising:
an encoder for encoding and prioritizing a raw video stream into n-partitions of progressively decreasing importance;
an MD-FEC encoder that spread the n-partitions across a set of n-descriptions and computes channel codes for the n-descriptions such that the n-partitions are protected by n-channel codes of decreasing strength;
a multi-channel streaming system for transmitting and receiving at least two coding formats
a. scalable-video and protection format of a prioritized encoded packet stream that has been further encoded by an FEC-MDC encoder, and
b. multiple description and protection of a prioritized encoded packet stream that has been further encoded by an FEC-MDC encoder; and
a mapping that maps the MD-FEC encoded n-descriptions to one of the at least two coding formats based on network channel conditions,
wherein said source employs said encoder to MD-FEC encode a prioritized video stream from a raw video stream, and based on network channel conditions employs said mapping to map the MD-FEC encoded stream to one of said at least two coding formats and employs said multi-channel streaming system to transmit said formatted stream over the network.

6. The apparatus of claim 5, wherein the multi-channel streaming system further comprises a plurality of hinting tracks, each of said plurality of hinting tracks being associated with at least one of said at least two coding formats.

7. The apparatus of claim 5, wherein said multi-channel streaming system further comprises:
a first multi-channel streaming system for said scalable-video and protection transmission and reception; and
a second multi-channel streaming system for said multiple-description and protection transmission and reception.

8. The apparatus of claim 7, wherein said first multi-channel streaming system further comprises:
a plurality of channels for concurrent transmission of a prioritized layer as a separate stream;
at least once FEC channel for transmission of at least one separate stream comprising FEC codes, wherein an FEC packet may be discarded based on good network channel conditions; and
an Automatic Repeat reQuest channel for transmission of at least a most important video packet of said received video stream, wherein said ARQ channel is transmitted in a delayed fashion.

9. A network comprising:
at least one source node of at least one raw video stream, said at least one source node comprising an apparatus according to claim 5 for encoding and transmitting said at least one raw video stream over the network using said multi-channel streaming system; and
at least one gateway node comprising an apparatus according to claim 1, for receiving, mapping, and transmitting an MD-FEC encoded stream according to network conditions.

10. A network comprising:
at least one source node of at least one raw video stream, said at least one source node comprising an apparatus according to claim 6 for encoding and transmitting said at least one raw video stream over the network using said multi-channel streaming system; and
at least one gateway node comprising an apparatus according to claim 2, for receiving, mapping, and transmitting an MD-FEC encoded stream according to network conditions.

11. A network comprising:
at least one source node of at least one raw video stream, said at least one source node comprising an apparatus according to claim 7 for encoding and transmitting said at least one raw video stream over the network using said multi-channel streaming system; and
at least one gateway node comprising an apparatus according to claim 3, for receiving, mapping, and transmitting an MD-FEC encoded stream according to network conditions.

12. A network comprising:
at least one source node of at least one raw video stream, said at least one source node comprising an apparatus according to claim 8 for encoding and transmitting said at least one raw video stream over the network using said multi-channel streaming system; and
at least one gateway node comprising an apparatus according to claim 4, for receiving, mapping, and transmitting an MD-FEC encoded stream according to network conditions.

13. A method for switching between a multi-channel streaming system for multiple-description and protection transmission and a multi-channel streaming system for scalable-video and protection transmission based on network channel conditions, comprising the steps of:
providing a multi-channel streaming system having at least two coding formats
a. scalable-video and protection format of a prioritized encoded packet stream that has been further encoded by an FEC-MDC encoder;
b. multiple description and protection format of a prioritized encoded packet stream that has been further encoded by an FEC-MDC encoder;
receiving a multi-channel packet stream formatted in accordance with one of said at least two coding formats;
probing the network to obtain channel conditions;
in accordance with obtained channel conditions, mapping between the scalable-video and multiple-description format as determined by the format of the received multi-channel video stream such that video data coding and channel coding of the FEC-MDC encoded prioritized encoded packet stream is preserved; and
retransmitting the mapped video stream with the provided multi-channel streaming system.

14. The method of claim 13, wherein the step of providing a multi-channel streaming system further comprises the step of providing a plurality of hinting tracks, each of said plurality of hinting tracks being associated with at least one of said at least two coding formats.

15. The method of claim 13, wherein the step of providing said multi-channel streaming system further comprises the steps of:
providing a first multi-channel streaming system for transmitting and receiving a video stream according to said scalable-video and protection format; and
providing a second multi-channel streaming system for transmitting and receiving a video stream according to said multiple-description and protection format.

16. A method for encoding a raw video stream for transmission and transmitting the encoded stream by a source over a multi-channel streaming system based on network channel conditions, comprising the steps of:
encoding and prioritizing a raw video stream into n-partitions of progressively decreasing importance;
spreading the n-partitions across a set of n-descriptions and computing channel codes for the n-descriptions such that the n-partitions are prioritized and protected by n-channel codes of decreasing strength;
providing a multi-channel streaming system for transmitting and receiving at least two coding formats:
a. scalable-video and protection format, and
b. multiple description and protection format; and
mapping the n-descriptions to one of the at least two coding formats based on network channel conditions; and
transmitting the mapped n-description by the provided multi-channel streaming system.

17. The method of claim 16, wherein the step of providing the multi-channel streaming system further comprises the step of providing a plurality of hinting tracks, each of said plurality of hinting tracks being associated with at least one of said at least two coding formats.

18. The method of claim 16, wherein the step ofproviding said multi-channel streaming system further comprises the steps of:
providing a first multi-channel streaming system for said scalable-video and protection transmission and reception; and
providing a second multi-channel streaming system for said multiple-description and protection transmission and reception.

19. A method for providing a network, comprising the steps of:
providing at least one source node of at least one raw video stream;
said at least one source node performing the method of claim 16 for encoding, protecting and transmitting said at least one raw video stream over the network using said multi-channel streaming system;
providing at least one gateway node; and
said at least one gateway node performing the method of claim 13, for receiving, mapping, and retransmitting said encoded and protected video stream according to network conditions.

20. A method for providing a network, comprising the steps of:
providing at least one source node of at least one raw video stream;
said at least one source node performing the method of claim 17 for encoding,
protecting and transmitting said at least one raw video stream over the network using said multi-channel streaming system;
providing at least one gateway node; and
said at least one gateway node performing the method of claim 13, for receiving, mapping, and retransmitting said encoded and protected video stream according to network conditions.

21. A method for providing a network, comprising the steps of:
providing at least one source node of at least one raw video stream;
said at least one source node performing the method of claim 18 for encoding, protecting and transmitting said at least one raw video stream over the network using said multi-channel streaming system;
providing at least one gateway node; and
said at least one gateway node performing the method of claim 13, for receiving, mapping, and retransmitting said encoded and protected video stream according to network conditions.
